(19) United States
(12) Patent Application Publication
(10) Pub. No.: US 2026/0255897 A1
(43) Pub. Date: Aug. 27, 2026

(54) METHOD OF METAL SURFACE TREATMENT USING GCIB FOR NEXT GENERATION INTERCONNECT

(71) Applicant: Tokyo Electron Limited, Tokyo (JP)

(72) Inventors: Soo Doo Chae, Albany, NY (US); Nicholas Joy, Albany, NY (US); Kai-Hung Yu, Albany, NY (US); Yan Shao, North Chelmsford, MA (US); Allen Leith, North Chelmsford, MA (US); Arkalgud Sitaram, Albany, NY (US)

(21) Appl. No.: 19/062,509

(22) Filed: Feb. 25, 2025

(51) Int. Cl. H01L 21/3213; H01L 21/285; H01L 21/3205

(52) U.S. Cl. CPC H10P 50/269; H10P 14/412; H10P 14/418

(57) ABSTRACT

A method of processing metal features in a semiconductor substrate comprises directing an amorphizing gas cluster ion beam at a metal-containing interconnect material to provide an amorphized metal-containing interconnect material; and annealing the amorphized metal-containing interconnect material in an amount effective to provide a recrystallized metal-containing interconnect material; wherein the metal-containing interconnect material is patterned during the method to form an interconnect. The resulting patterned lines of metal-containing interconnect material exhibit excellent resistivity properties.

### FIELD

The present invention relates to surface treatment of metal-containing materials in small pitch structures, such as integrated circuit structures.

### BACKGROUND

In the semiconductor industry, increasing circuit density drives progress toward smaller and smaller dimensions and larger numbers of transistors placed in an individual device. Metal features in microelectronic devices include contacts and interconnects (i.e., wiring). Metal features in semiconductor devices can be formed by strategies such as damascene techniques and/or metal patterning techniques. In damascene techniques, trenches and vias are formed in a dielectric material, such as by etching, and then the trenches and vias are filled with metal, such as copper or other metal. Patterning techniques involve patterning metal films to form patterned metal features, typically by etching. In contrast to other dielectric materials, metal materials are more challenging to etch; hence, damascene strategies are often used to form metal interconnects. Damascene techniques include dual damascene, single damascene, and semi-damascene strategies. The “single” damascene process involves creating and filling the trenches (or vias) first and then proceeding to fill the trenches (or vias). Then, the etching and filling is repeated for the vias (or trenches). A “Dual” damascene process forms the trenches and vias at the same time and then fills both the trench and vias at the same time.

Gas cluster ion beam (“GCIB”) processes are disclosed in U.S. Pat. No. 11,450,506 that may be used to edit features within a patterned layer to provide feature sizes smaller than the resolution limit of the photolithography system used to form the initial pattern. Additionally, this patent notes that random variations in critical dimensions in a pattern result from surface roughness of sidewalls along the edges of features, such as lines, trenches, pillars, and holes within a patterned layer, and states that GCIB processes can enhance a patterned layer by smoothing the surfaces of features by trimming random protrusions from exposed surfaces using a GCIB. Additionally, this patent states that GCIB trim etch process may also be applied to descum a patterned layer. The use of a GCIB to smooth a solid surface of substrate of e.g. a semiconductor is described in US Patent Application Publication Number 2014/0299465. In this disclosure, the angle formed between the solid surface and the GCIB is chosen to be between 1° and an angle less than 30°.

A method for removing and/or redistributing material in the trenches and/or vias of integrated circuit interconnect structures by a gas cluster ion beam (GCIB) is described in U.S. Pat. No. 7,115,511 to improve the fabrication process and quality of metal interconnects in an integrated circuit. This patent expressly notes that “The etching/sputtering of the barrier material and/or copper seed material present on the interconnect trench or via sidewall is greatly minimized by the use of a gas cluster ion beam applied at approximately normal incidence to the surface of the integrated circuit (which is approximately parallel to the axis of the cylindrical interconnect via, or in the case of a trench-like via, approximately parallel to the median plane of the trench)” at column 7, lines 12-19.

### SUMMARY

As semiconductor device feature size continues to scale to smaller sizes, it is becoming an increasing challenge to reduce the device contact resistance, especially for devices having very small features using the conventional dual or single damascene flow strategies. Some aspects of next generation metallization are using semi damascene or subtractive metal etch flow. In a next generation technique, alternative interconnect metals, such as Ru, Mo, Nb, W, Ti, TiN, Ta, TaN, and Co with subtractive metal etch techniques are used to form small metal features to replace Cu. These interconnect metals, which have better electric properties and/or advantages of process fabrication compared to Cu as the metal critical dimensions (“CD”) become small, are deposited and then etched to form patterned metal features. In short, subtractive metal etch strategies form small metal features using patterning, and other larger metal features are formed using damascene techniques.

As the dimensions of integrated circuits (“IC”) are reduced and as the component density is increased, significant challenges arise in processing of such features. While the next generation interconnect metals are expected to show less metal migration, these materials may exhibit actual resistivity that is higher than expected due to surface scattering and grain boundary scattering.

It has been found that the resistivity properties of patterned lines of metal-containing interconnect materials as described herein are improved by directing an amorphizing GCIB at the metal-containing interconnect material to provide an amorphized metal-containing interconnect material, followed by annealing the amorphized metal-containing interconnect material in an amount effective to provide a recrystallized metal-containing interconnect material. The interconnect material is patterned during the method to form an interconnect. The resistivity properties of metal-containing interconnect material when treated with both the amorphizing GCIB and the annealing step are substantially improved as compared to like metal-containing interconnect materials that have only been treated with one of either the amorphizing GCIB or the annealing step.

It has been found that an amorphizing GCIB when directed at a metal-containing interconnect material is highly effective in precisely forming an amorphized metal-containing interconnect material. This amorphized metal-containing interconnect material is then annealed to provide a recrystallized metal-containing interconnect material that exhibits excellent resistivity properties. The stepwise process of treatment with an amorphizing GCIB followed by annealing to recrystallize the metal-containing interconnect material has been found to increase grain size. In an embodiment, the specular reflection in the surface of metal-containing interconnect material is increased.

In an embodiment of the present invention, the LER (Line Edge Roughness) of metal-containing interconnect material is improved by directing an amorphizing GCIB at the metal-containing interconnect material to provide an amorphized metal-containing interconnect material; and annealing the amorphized metal-containing interconnect material in an amount effective to provide a recrystallized metal-containing interconnect material.

In an embodiment of the present invention, it has been found that directing an amorphizing gas cluster ion beam (GCIB) at the metal-containing interconnect material advantageously provides nano-scale modification of the interconnect. Since the amorphizing gas cluster ion beam may be controlled with precision, modification of the interconnect can be carried out with high precision relative to the area and depth of the interconnect and degree of energy imparted to the interconnect material.

### BRIEF DESCRIPTION OF THE DRAWINGS

The accompanying drawings, which are incorporated in and constitute a part of this application, illustrate several aspects of the invention and together with a description of the embodiments explain the principles of the invention. A brief description of the drawings is as follows:

FIG. 1 is a schematic graphical illustration of a view of a prior art method of processing a metal-containing interconnect material on a semiconductor substrate.

FIG. 2 is a schematic graphical illustration of a view of a method of processing a metal-containing interconnect material on a semiconductor substrate.

FIG. 3 is a schematic graphical illustration of a view of a method of processing a metal-containing interconnect material on a semiconductor substrate.

FIG. 4 is a photograph showing grains of a metal-containing interconnect material that has only been annealed.

FIG. 5 is a second photograph showing grains of a metal-containing interconnect material that has only been annealed.

FIG. 6 is a photograph showing grains of a metal-containing interconnect material that has been amorphized by a GCIB, followed by annealing.

FIG. 7 is a second photograph showing grains of a metal-containing interconnect material that has been amorphized by a GCIB, followed by annealing.

FIG. 8 is a graph showing grain radius size distribution data of a metal-containing interconnect material that has been amorphized by a GCIB followed by annealing; and of a metal-containing interconnect material that has been annealed, but not amorphized by a GCIB.

FIG. 9 is a graph showing resistivity of metal-containing interconnect material that has been amorphized by a GCIB but not annealed, as compared to metal-containing interconnect material that has been amorphized by a GCIB followed by annealing.

### DETAILED DESCRIPTION

The aspects of the present invention described below are not intended to be exhaustive or to limit the invention to the precise forms disclosed in the following detailed description. Rather a purpose of the aspects chosen and described is by way of illustration or example, so that the appreciation and understanding by others skilled in the art of the general principles and practices of the present invention can be facilitated.

As noted above, next generation interconnect metals may exhibit actual resistivity that is higher than expected due to surface scattering and grain boundary scattering. The nanoscale resistivity of the interconnect is the sum of contributions to the bulk resistivity of each material from electron scattering by the external surface and by the grain boundary scattering as indicated by the following formula (1):

$${ρ}_{total} = {ρ}_{0} + {ρ}_{0} λ \frac{3 ( 1 - p )}{4 d} + {ρ}_{0} λ \frac{3 R}{2 D ( 1 - R )} \qquad ( 1 )$$

The present method effectively increases grain size. In an embodiment, the present method decreases the line Edge Roughness (“LER”), thereby improving the resistivity in patterned lines.

In an embodiment, the recrystallized metal-containing interconnect material has a mean grain size area of greater than 230 nm². In an embodiment, the recrystallized metal-containing interconnect material has a mean grain size area of greater than 240 nm². In an embodiment, the recrystallized metal-containing interconnect material has a mean grain size area of greater than 250 nm².

In an embodiment, the recrystallized metal-containing interconnect material has a grain radius mean of from 7 nm to 9 nm, a grain radius mode of from 7 nm to 9 nm, and a grain radius standard deviation of greater than 3.

In an embodiment, the recrystallized metal-containing interconnect material has a resistivity that is reduced by at least 10% as compared to the resistivity of a like interconnect material that has not been treated by an amorphizing gas cluster ion beam. In an embodiment, the recrystallized metal-containing interconnect material has a resistivity that is reduced by at least 11% as compared to the resistivity of a like interconnect material that has not been treated by an amorphizing gas cluster ion beam. In an embodiment, the recrystallized metal-containing interconnect material has a resistivity that is reduced by 15% as compared to the resistivity of a like interconnect material that has not been treated by an amorphizing gas cluster ion beam.

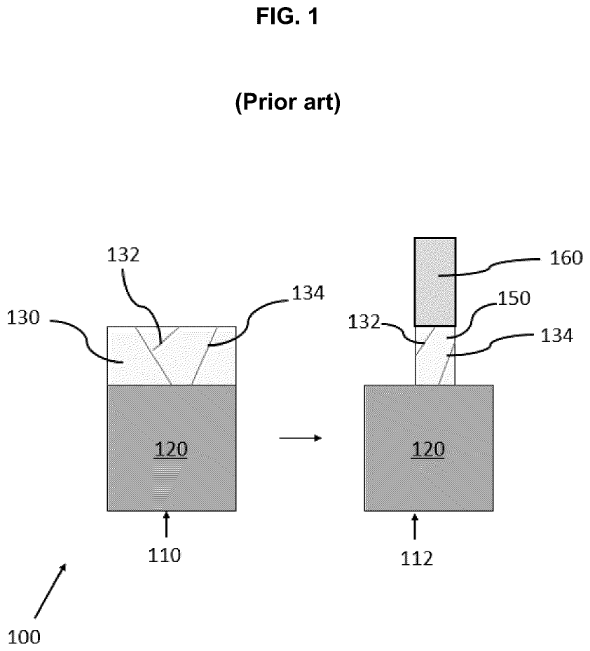

Turning now to the Figures, FIG. 1 is a schematic graphical illustration of a prior art process 100 of preparing a metal-containing interconnect material in a semiconductor substrate a process flow of prior art BEOL integration using a subtractive etch process. In the process, intermediate structure 110 comprises metal-containing material layer 130 provided on semiconductor substrate 120. Due to the polycrystalline nature of the metal-containing material layer 130, grain boundaries 132 and 134 are present in metal-containing material layer 130.

Metal-containing material layer 130 is patterned by conventional patterning techniques, such as by facilitate subtractive etching. In this process, intermediate structure 110 is provided with hard mask 160 to facilitate subtractive etching, and is etched to form intermediate structure 112 comprising interconnect 150 (as shown, under hard mask 160). The metal-containing material of interconnect 150 still comprises grain boundaries 132 and 134. Additionally, due to the nature of the line patterning process, the LER of interconnect 150 is unsatisfactory. Metal-containing material interconnects prepared by such a prior art method exhibit high resistivity properties.

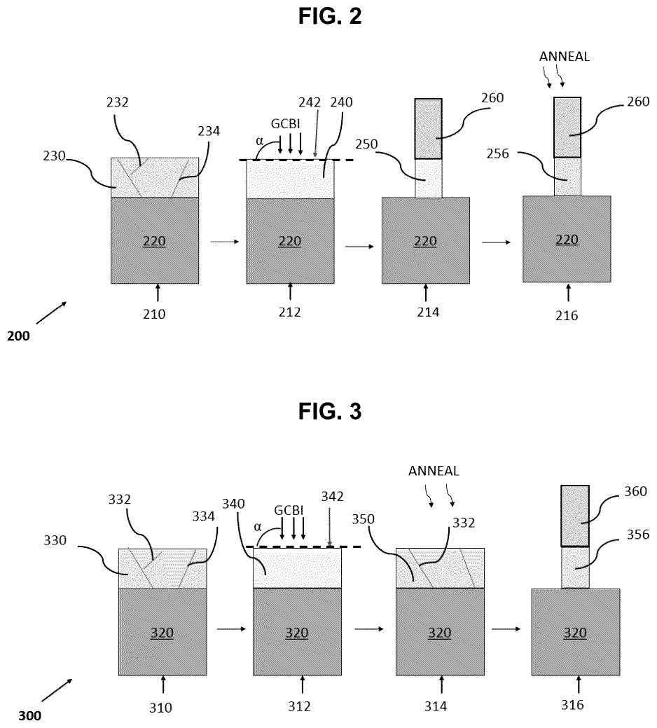

FIG. 2 is a schematic graphical illustration of a view of a method 200 of preparing a metal-containing interconnect material in a semiconductor substrate, illustrated using a subtractive etch process. It will be appreciated that the process steps of process of treatment of the metal-containing interconnect material with an amorphizing GCIB followed by annealing to recrystallize the metal-containing interconnect material as exemplified in the present figures may be employed using other techniques for preparing a metal-containing interconnect material in a semiconductor substrate, such as dual or single damascene processes.

In the process, intermediate structure 210 comprises metal-containing material layer 230 provided on semiconductor substrate 220. Metal-containing material layer 230 may be deposited on semiconductor substrate 220 by any appropriate process, such as physical vapor deposition (PVD), chemical vapor deposition (CVD), electrodeposition (ED), and atomic layer deposition (ALD).

In an embodiment, the metal-containing material of the metal-containing interconnect material is selected from Ru, Mo, Nb, W, Ti, TiN, Ta, TaN, and Co. In an embodiment, the metal-containing material of the metal-containing interconnect material is selected from Ru, Mo, Nb, W, Co and alloys of any one of Ru, Mo, Nb, W, and Co. In an embodiment, the metal-containing material of the metal-containing interconnect material is selected from Ru or an Ru alloy thereof, wherein the Ru alloy comprises at least one metal selected from Cu, Co, W, Al, Ti and transition metals.

Due to the polycrystalline nature of the metal-containing material layer 230, grain boundaries 232 and 234 are present in metal-containing material layer 230. An amorphizing GCIB is directed at a surface 242 of the metal-containing material layer 230 at an angle α to provide an amorphized metal-containing interconnect material 240 as shown in intermediate structure 212.

In an embodiment, the amorphizing GCIB used in the present method comprises an inert gas selected from nitrogen, helium, neon, argon, krypton, and xenon. In an embodiment, the amorphizing GCIB used in the present method comprises inert gas and further comprises O₂ gas.

A hard mask 260 is applied to a selected portion of amorphized metal-containing interconnect material 240 to facilitate formation of amorphized interconnect 250 by a subtractive etch process, as shown in intermediate structure 214.

In an embodiment, the hard mask comprises a material selected from SiO₂, Si, SiCN, titanium nitride (TiN), titanium oxide (TiO₂), tungsten carbide (WC), WSi, WSiN, tungsten alloys, SiN, SnO₂, organic hard masks, and metal oxide hard masks.

Amorphized interconnect 250 is then annealed by an appropriate annealing method, such as high temperature furnace annealing, laser annealing, microwave annealing, flash lamp annealing, and intense pulse light annealing, to provide recrystallized interconnect 256, as shown in intermediate 216. In an embodiment, the annealing takes place at a temperature of not more than about 400° C.

Upon recrystallization, the resulting recrystallized interconnect exhibits increased grain size, decreased Line Edge Roughness (“LER”), and/or a reduction in the grain boundary contribution to resistance, thereby improving the resistivity in patterned lines.

FIG. 3 is a schematic graphical illustration of a view of a method 300 of preparing a metal-containing interconnect material in a semiconductor substrate, illustrated using a subtractive etch process. In the process, intermediate structure 310 comprises metal-containing interconnect material 330 provided on semiconductor substrate 320. Metal-containing interconnect material 330 may be deposited on semiconductor substrate 320 by any appropriate process, such as physical vapor deposition (PVD), chemical vapor deposition (CVD), electrodeposition (ED), and atomic layer deposition (ALD).

Due to the polycrystalline nature of the metal-containing interconnect material 330, grain boundaries 332 and 334 are present in metal-containing interconnect material 330 as shown in intermediate structure 310. An amorphizing GCIB is directed at a surface 342 of the metal-containing interconnect material 330 at an angle α to provide an amorphized metal-containing interconnect material 340 as shown in intermediate structure 312.

In contrast with the embodiment shown in FIG. 1, amorphized metal-containing interconnect material 340 is then annealed by an appropriate annealing method, such as high temperature furnace annealing, laser annealing, microwave annealing, flash lamp annealing, and intense pulse light annealing, to provide recrystallized metal-containing interconnect material 350, as shown in intermediate structure 314. Note that recrystallized metal-containing interconnect material 350 may have a limited number of grain boundaries 332 present upon recrystallization, but much less than are observed in original intermediate structure 310.

After annealing, a hard mask 360 is applied to a selected portion of recrystallized metal-containing interconnect material 350 to facilitate formation of recrystallized interconnect 356 by a subtractive etch process, as shown in intermediate structure 316.

As the processes as shown in FIGS. 2 and 3 illustrate, the metal-containing interconnect material is patterned at some time during the method to form an interconnect. In an embodiment, the interconnect material is patterned after the directing of the amorphizing GCIB at the metal-containing interconnect material and before the annealing of the amorphized metal-containing interconnect material. In an embodiment, the interconnect material is patterned after the directing of the amorphizing GCIB at the metal-containing interconnect material and after the annealing of the amorphized metal-containing interconnect material.

The interconnect material is patterned to provide an interconnect having a linewidth suitable for connection of small semiconductor device features. In an embodiment, the interconnect has a linewidth after patterning of less than 30 nm. In an embodiment, the interconnect has a linewidth after patterning of less than 25 nm. In an embodiment, the interconnect has a linewidth after patterning of less than 20 nm. In an embodiment, the interconnect has a linewidth after patterning of less than 15 nm.

Gas cluster ion beam devices (“GCIB devices”) are known in the art and are described, for example, in U.S. Pat. Nos. 7,115,511; 7,550,748; 9,209,033; 11,450,506; and US Patent Application Publication Number 2014/0299465, the disclosures of which are incorporated by reference herein for purposes of describing components of GCIB devices, configurations of components of GCIB devices and materials used in operation of components of GCIB devices.

In general, a GCIB device may be described as follows: a vacuum vessel is divided into three communicating chambers, a source chamber, an ionization/acceleration chamber, and a processing chamber. The three chambers are evacuated to suitable operating pressures by vacuum pumping systems. A condensable source gas (for example argon or N2) stored in a gas storage cylinder is admitted under pressure through a gas metering valve and gas feed tube into stagnation chamber and is ejected into the substantially lower pressure vacuum through a properly shaped nozzle, providing a supersonic gas jet. Cooling, which results from the expansion in the jet, causes a portion of the gas jet to condense into clusters, each consisting of from several to several thousand weakly bound atoms or molecules. A gas skimmer aperture partially separates the gas molecules that have not condensed into a cluster jet from the cluster jet so as to minimize pressure in the downstream regions where such higher pressures would be detrimental (e.g., ionizer, high voltage electrodes, and process chamber). Suitable condensable source gases include, but are not necessarily limited to one or more inert gases such as argon and nitrogen.

After the supersonic gas jet containing gas clusters has been formed, the clusters are ionized in an ionizer. The ionizer is typically an electron impact ionizer that produces thermoelectrons from one or more incandescent filaments and accelerates and directs the electrons causing them to collide with the gas clusters in the gas jet, where the jet passes through the ionizer. The electron impact ejects electrons from the clusters, causing a portion the clusters to become positively ionized. A set of suitably biased high voltage electrodes extracts the cluster ions from the ionizer, forming a beam, then accelerates them to a desired energy (typically from 1 keV to several tens of keV) and focuses them to form a GCIB. Filament power supply provides voltage VF to heat the ionizer filament. Anode power supply provides voltage VA to accelerate thermoelectrons emitted from filament to cause them to irradiate the cluster containing gas jet to produce ions. Extraction power supply provides voltage VE to bias a high voltage electrode to extract ions from the ionizing region of ionizer and to form a GCIB. Accelerator power supply provides voltage V_{ACC} to bias a high voltage electrode with respect to the ionizer so as to result in a total GCIB acceleration energy equal to V_{ACC} electron volts (eV). One or more lens power supplies may be provided to bias high voltage electrodes with potentials to focus the GCIB.

### EXAMPLES

Interconnect materials were prepared and treated to show the benefit of the present process of treatment by directing an amorphizing GCIB at the metal-containing interconnect material to provide an amorphized metal-containing interconnect material in combination with annealing the amorphized metal-containing interconnect material in an amount effective to provide a recrystallized interconnect material. The interconnect metal used in the present examples was a Ruthenium metal deposited by PVD at a 30 nm thickness.

### Example 1 (Comparative)

A first sample was prepared wherein the metal-containing interconnect material was not treated by directing an amorphizing GCIB at the metal-containing interconnect material to provide an amorphized metal-containing interconnect material, but only by annealing the metal-containing interconnect material in an amount effective to provide a recrystallized interconnect material.

### Example 2

A second sample was prepared wherein the metal-containing interconnect material was treated by directing an amorphizing GCIB at the metal-containing interconnect material to provide an amorphized metal-containing interconnect material, and additionally was annealed in an amount effective to provide a recrystallized interconnect material.

### Example 3 (Comparative)

A third sample was prepared wherein the metal-containing interconnect material was treated by directing an amorphizing GCIB at the metal-containing interconnect material to provide an amorphized metal-containing interconnect material, but not annealed.

Grain radius size distribution of these samples was determined by manual analysis and measurement of Transmission Electron Microscope (TEM) images.

Photographs showing grains of the metal-containing interconnect material were taken by TEM at a magnification suitable to accurately measure the ruthenium grains.

Resistivity of metal-containing interconnect materials was measured with a 4 point probe on 30 nm blanket Ru using the same tool for all measurements to compare differences between the samples being evaluated, rather than relying on absolute values of the measurement.

### Data and Discussion

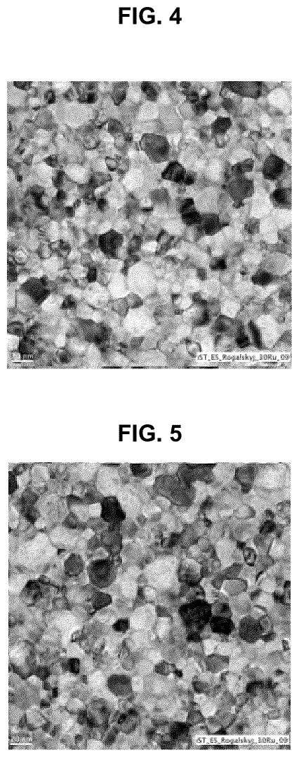

FIGS. 4 and 5 are photographs showing grains of the metal-containing interconnect material of Comparative Example 1 (i.e., that has only been annealed).

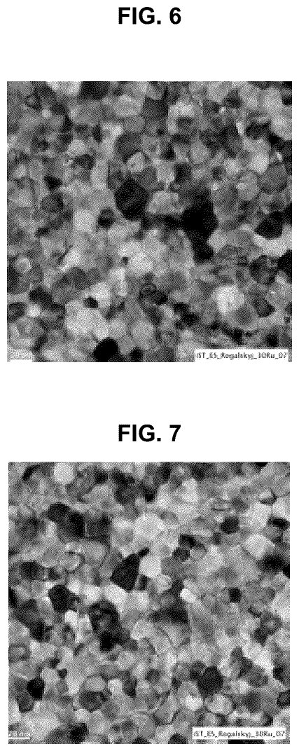

FIGS. 6 and 7 are photographs showing grains of a metal-containing interconnect material of Example 2 (i.e., that has been amorphized by a GCIB, followed by annealing).

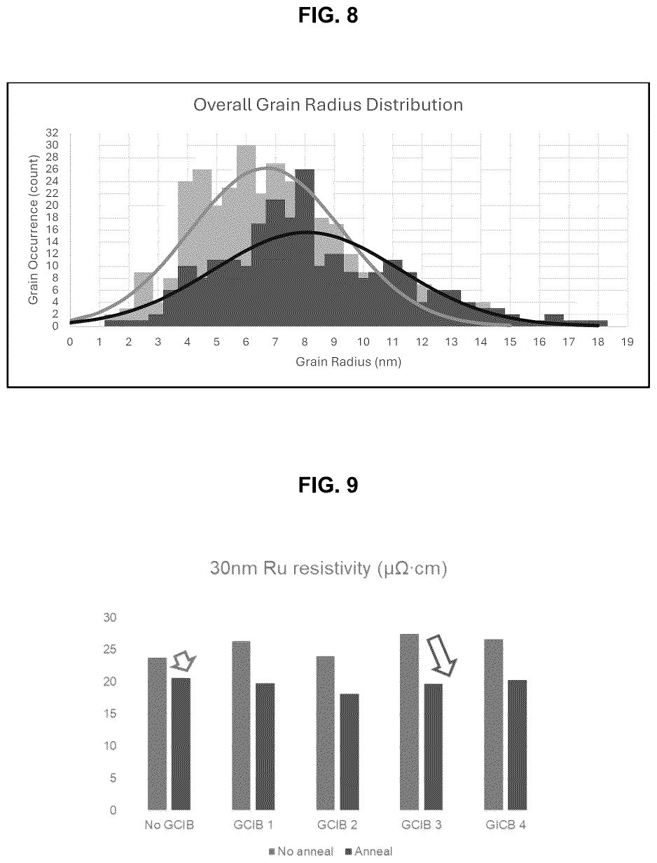

FIG. 8 is a graph showing grain radius size distribution data of a metal-containing interconnect material of Example 2 (i.e., that has been amorphized by a GCIB, followed by annealing); and of a metal-containing interconnect material of Comparative Example 1 (i.e., that has only been annealed). The data presented in FIG. 8 was generated by drawing a diagonal line from one corner of the sample image to the other, and measuring the size of any grain that touched the line.

The graphs and photographs of grain size as shown in these figures reveal that the GCIB processed and annealed sample has a larger mean grain size as compared to sample without GCIB processing. Although the distribution widens, it is skewed more towards the larger grain size, with a reduction in the number of smaller grains. It is expected that this reduction in smaller grain sizes will provide a greater benefit to patterned metal resistance than the shift in mean grain size would otherwise indicate.

FIG. 9 is a graph showing resistivity of metal-containing interconnect material of Comparative Example 3 (i.e., that has only been amorphized), as compared to metal-containing interconnect material of Example 2 (i.e., that has been amorphized by a GCIB, followed by annealing).

Numerical data as shown in FIG. 9 is presented in Table 1 as follows:

TABLE 1

| | | | % reduction in |
|---|---|---|---|
| | | | resistivity before/ |
| | No anneal | Anneal | after the anneal |
| No GCIB | 23.8 μΩ · cm | 20.6 μΩ · cm | 13.4% reduction |
| GCIB 1 | 26.4 μΩ · cm | 19.8 μΩ · cm | 25% reduction |
| GCIB 2 | 24 μΩ · cm | 18.2 μΩ · cm | 24% reduction |
| GCIB 3 | 27.5 μΩ · cm | 19.7 μΩ · cm | 28.4% reduction |
| GICB 4 | 26.7 μΩ · cm | 20.3 μΩ · cm | 24% reduction |

The graph as shown in this figure reveals that a substantial reduction in resistivity of metal-containing interconnect material was achieved by the present method.

As used herein, the terms “about” or “approximately” mean within an acceptable range for the particular parameter specified as determined by one of ordinary skill in the art, which will depend in part on how the value is measured or determined, e.g., the limitations of the sample preparation and measurement system. Examples of such limitations include preparing the sample in a wet versus a dry environment, different instruments, variations in sample height, and differing requirements in signal-to-noise ratios. For example, “about” can mean greater or lesser than the value or range of values stated by 1/10 of the stated values, but is not intended to limit any value or range of values to only this broader definition. For instance, a concentration value of 30% means a concentration between 27% and 33%. Each value or range of values preceded by the term “about” is also intended to encompass the embodiment of the stated absolute value or range of values.

Throughout this specification and claims, unless the context requires otherwise, the word “comprise”, and variations such as “comprises” and “comprising”, will be understood to imply the inclusion of a stated integer or step or group of integers or steps but not the exclusion of any other integer or step or group of integer or step. When used herein “consisting of” excludes any element, step, or ingredient not specified in the claim element. When used herein, “consisting essentially of” does not exclude materials or steps that do not materially affect the basic and novel characteristics of the claim. In the present disclosure of various embodiments, any of the terms “comprising”, “consisting essentially of” and “consisting of” used in the description of an embodiment may be replaced with either of the other two terms.

All patents, patent applications (including provisional applications), and publications cited herein are incorporated by reference as if individually incorporated for all purposes. Unless otherwise indicated, all parts and percentages are by weight and all molecular weights are weight average molecular weights. The foregoing detailed description has been given for clarity of understanding only. No unnecessary limitations are to be understood therefrom. The invention is not limited to the exact details shown and described, for variations obvious to one skilled in the art will be included within the invention defined by the claims.

1. A method of processing metal features in a semiconductor substrate, the method comprising:
providing a semiconductor substrate comprising a metal-containing interconnect material, wherein the metal-containing interconnect material comprises a metal selected from Ru, Mo, Nb, W, Ti, TiN, Ta, TaN, and Co;
directing an amorphizing gas cluster ion beam at the metal-containing interconnect material to provide an amorphized metal-containing interconnect material; and
annealing the amorphized metal-containing interconnect material in an amount effective to provide a recrystallized metal-containing interconnect material;
wherein the metal-containing interconnect material is patterned during the method to form an interconnect.

2. The method of claim 1, wherein the metal-containing material of the metal-containing interconnect material is selected from Ru, Mo, Nb, W, Co and alloys of any one of Ru, Mo, Nb, W, and Co.

3. The method of claim 1, wherein the metal-containing material of the metal-containing interconnect material is selected from Ru or an Ru alloy thereof, wherein the Ru alloy comprises at least one metal selected from Cu, Co, W, Al, Ti and transition metals.

4. The method of claim 1, wherein the recrystallized metal-containing interconnect material has a mean grain size area of greater than 230 nm².

5. The method of claim 1, wherein the recrystallized metal-containing interconnect material has a mean grain size area of greater than 240 nm².

6. The method of claim 1, wherein the recrystallized metal-containing interconnect material has a mean grain size area of greater than 250 nm².

7. The method of claim 1, wherein the recrystallized metal-containing interconnect material has a grain radius mean of from 7 nm to 9 nm, a grain radius mode of from 7 nm to 9 nm, and a grain radius standard deviation of greater than 3.

8. The method of claim 1, wherein the recrystallized metal-containing interconnect material has a resistivity that is reduced by at least 10% as compared to the resistivity of a like metal-containing interconnect material that has not been treated by an amorphizing gas cluster ion beam.

9. The method of claim 1, wherein the recrystallized metal-containing interconnect material has a resistivity that is reduced by at least 11% as compared to the resistivity of a like metal-containing interconnect material that has not been treated by an amorphizing gas cluster ion beam.

10. The method of claim 1, wherein the recrystallized metal-containing interconnect material has a resistivity that is reduced by 15% as compared to the resistivity of a like metal-containing interconnect material that has not been treated by an amorphizing gas cluster ion beam.

11. The method of claim 1, wherein the gas cluster ion beam comprises an inert gas selected from nitrogen, helium, neon, argon, krypton, xenon, and mixtures thereof.

12. The method of claim 11, wherein the gas cluster ion beam further comprises O₂ gas.

13. The method of claim 1, wherein the annealing step comprises an anneal method selected from high temperature furnace annealing, laser annealing, microwave annealing, flash lamp annealing, and intense pulse light annealing.

14. The method of claim 1, wherein the interconnect material is patterned after the directing of the amorphizing gas cluster ion beam at the metal-containing interconnect material and before the annealing of the amorphized metal-containing interconnect material.

15. The method of claim 1, wherein the metal-containing interconnect material is patterned after the directing of the amorphizing gas cluster ion beam at the metal-containing interconnect material and after the annealing of the amorphized metal-containing interconnect material.

16. The method of claim 1, wherein the metal-containing interconnect material is patterned using a subtractive etch process.

17. The method of claim 1, wherein the metal-containing interconnect material is patterned using a dual damascene process.

18. The method of claim 1, wherein the metal-containing interconnect material is patterned using a single damascene process.

19. The method of claim 1, wherein the metal-containing interconnect material has a linewidth after patterning of less than 30 nm, or wherein the metal-containing interconnect material has a linewidth after patterning of less than 25 nm, or wherein the metal-containing interconnect material has a linewidth after patterning of less than 20 nm, or wherein the metal-containing interconnect material has a linewidth after patterning of less than 15 nm.

20. The method of claim 1, wherein the metal-containing interconnect material has been deposited on the semiconductor substrate by a deposition method selected from physical vapor deposition (PVD), chemical vapor deposition (CVD), electrodeposition (ED), and atomic layer deposition (ALD).
